(19) United States
(12) Patent Application Publication
(10) Pub. No.: US 2011/0233583 A1
(43) Pub. Date: Sep. 29, 2011

(54) HIGH-POWER LED PACKAGE

(75) Inventors: Chen-Wei Lin, Zhongli City, (TW); Chia-Yu Liao, Zhongli City (TW)

(73) Assignee: H&T ELECTRONICS CO., LTD., Zhongli City (TW)

(21) Appl. No.: 12/748,392

(22) Filed: Mar. 27, 2010

(51) Int. Cl. H01L 33/00

(52) U.S. Cl. 257/98; 257/E33.056

(57) ABSTRACT

A high-power LED package includes a thermal conductive substrate, a circuit layer formed on the top wall of the thermal conductive substrate, a LED chip mounted on the top wall of the thermal conductive substrate, lead wires electrically connected between the LED chip and the circuit layer, and a packaging layer covering the LED chip, the lead wires and the connection areas between the lead wires and the circuit layer outside the bottom wall of the thermal conductive substrate for enabling waste heat to be directly transferred from the LED chip to the thermal conductive substrate and then rapidly dissipated into the outside open air by the thermal conductive substrate during operation of the LED chip.

### BACKGROUND OF THE INVENTION

1. Field of the Invention

The present invention relates to LED package technology and more particularly, to a high-power LED package, which has the characteristics of high performance, low power consumption, high reliability and long life span.

2. Description of the Related Art

The luminous efficiency of regular LEDs (light emitting diodes) is about 15˜20%, i.e., only about 15˜20% of inputted electric energy is converted into light energy, and the rest 80˜85% of inputted electric energy is converted into thermal energy. A relatively higher power LED generates a relatively greater amount of thermal energy during operation. If a LED package cannot effectively dissipate thermal energy, thermal energy will be cumulated inside the package, causing a rise in the contact point temperature. When the contact point temperature rises, the luminous efficiency of the LED package will drop, and the emission wavelength will become shortened, leading to shortening of the life span. The fabrication of a LED package includes the processed of die attach, wire bonding and molding. The process of die attach is to attach a LED chip to a lead frame or substrate. The process of wire bonding is to bond the ends of 10 μm gold or aluminum lead wires to the LED chip and the lead frame/substrate by mean of thermal bonding, ultrasonic wedge bonding or ultrasonic bonding. The process of molding is to mold epoxy resin on the lead frame or substrate to protect the LED chip. However, because contact point temperature=thermal resistance of package×consumed power+package internal temperature, epoxy resin will turn yellow a certain length of time under a high temperature environment, lowering the transparency and reducing the light output. Some manufactures use heat resistant photo-curable silicone rubber to replace epoxy resin for molding. However, because the cost of photo-curable silicone rubber is about 100 times over epoxy resin, using photo-curable silicone rubber to substitute for epoxy resin greatly increase LED package cost. Therefore, the heat dissipation of LED package is a subject to be settled.

### SUMMARY OF THE INVENTION

The present invention has been accomplished under the circumstances in view. It is one object of the present invention to provide a high-power LED package, which has the characteristics of high performance, low power consumption, high reliability and long life span.

To achieve this and other objects of the present invention, a high-power LED package comprises a thermal conductive substrate, a circuit layer formed on the top wall of the thermal conductive substrate, a LED chip mounted on the top wall of the thermal conductive substrate, lead wires electrically connected between the LED chip and the circuit layer, and a packaging layer covering the LED chip, the lead wires and the connection areas between the lead wires and the circuit layer outside the bottom wall of the thermal conductive substrate for enabling waste heat to be directly transferred from the LED chip to the thermal conductive substrate and then rapidly dissipated into the outside open air by the thermal conductive substrate during operation of the LED chip.

Further, a heat transfer layer may be sandwiched between the top wall of the thermal conductive substrate and the LED chip for quick transfer of waste heat from the LED chip to the thermal conductive substrate for dissipation by the thermal conductive substrate into the outside open air rapidly.

### BRIEF DESCRIPTION OF THE DRAWINGS

FIG. 1 is a schematic sectional side view showing the fabrication of a high-power LED package in accordance with the present invention (I).

FIG. 2 is a schematic sectional side view showing the fabrication of a high-power LED package in accordance with the present invention (II).

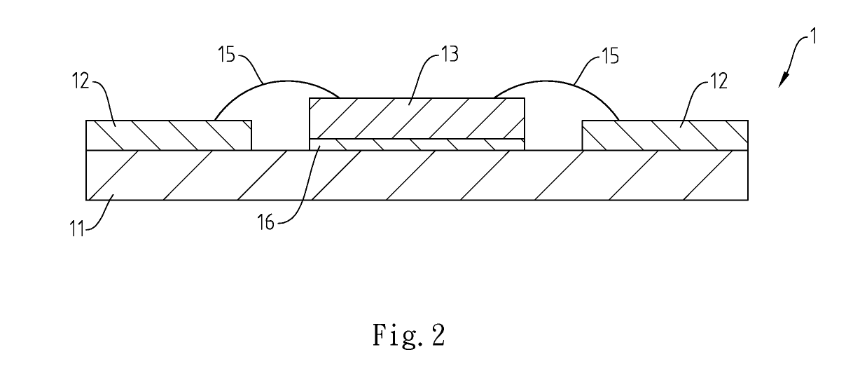

FIG. 3 is a schematic sectional side view showing the fabrication of a high-power LED package in accordance with the present invention (III).

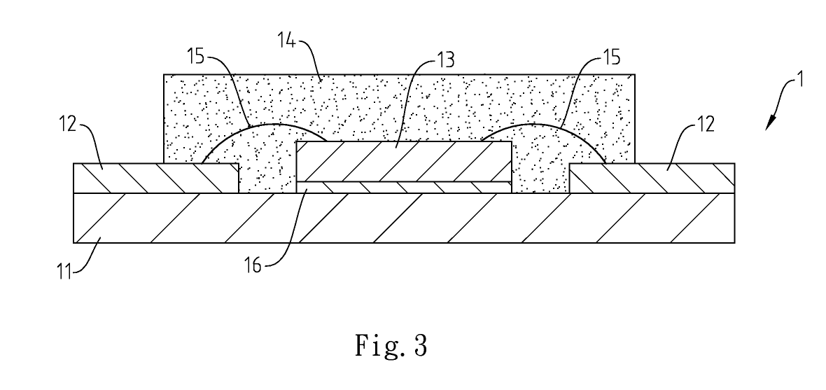

FIG. 4 is a schematic sectional side view of an alternate form of the high-power LED package in accordance with the present invention.

FIG. 5 is a schematic sectional side view of another alternate form of the high-power LED package in accordance with the present invention.

### DETAILED DESCRIPTION OF THE PREFERRED EMBODIMENT

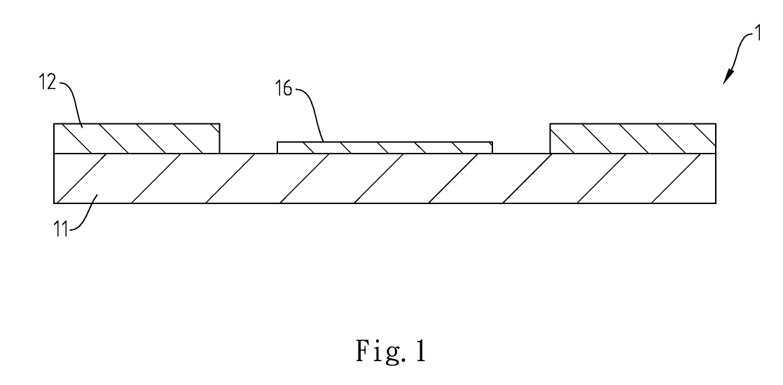

Referring to FIGS. 1˜3, a high-power LED package 1 in accordance with the present invention is made by: (1) preparing a thermal conductive substrate 11 from a material having a high heat transfer coefficient, for example, copper or aluminum; (2) forming a circuit layer 12 and a bonding layer 16 on the surface of the thermal conductive substrate 11, wherein the bonding layer 16 is formed by coating a solder material on the surface of the thermal conductive substrate 11; (3) mounting a LED chip 13 on the bonding layer 16; (4) bonding gold or aluminum lead wires of diameter about 10 μm to electrically connect the LED chip 13 to the circuit layer 12; and (5) applying a packaging material, for example, silver adhesive or epoxy resin to the thermal conductive substrate 11 to form a packaging layer 14 that covers the LED chip 13, the lead wires 15 and the connection areas between the lead wires 15 and the circuit layer 12 without reaching the periphery and bottom side of the thermal conductive substrate 11.

During application of the high-power LED package 1, the circuit layer 12 is connected to an external power source so that electricity is transmitted through the lead wires 15 to the LED chip 13, causing the LED chip 13 to emit light. Because the LED chip 13 is bonded to the bonding layer 16 at the thermal conductive substrate 11, the bonding layer 16 transfers waste heat directly from the LED chip 13 to the thermal conductive substrate 11 for quick dissipating into the outside open air. Because the packaging layer 14 simply encapsulates the LED chip 13, the lead wires 15 and the connection areas between the lead wires 15 and the circuit layer 12. As stated above, the packaging layer 14 simply covers the LED chip 13, the lead wires 15 and the connection areas between the lead wires 15 and the circuit layer 12 without reaching the periphery and bottom side of the thermal conductive substrate 11, the thermal conductive substrate 11 can dissipate waste heat from the LED chip 13 into the outside open air rapidly.

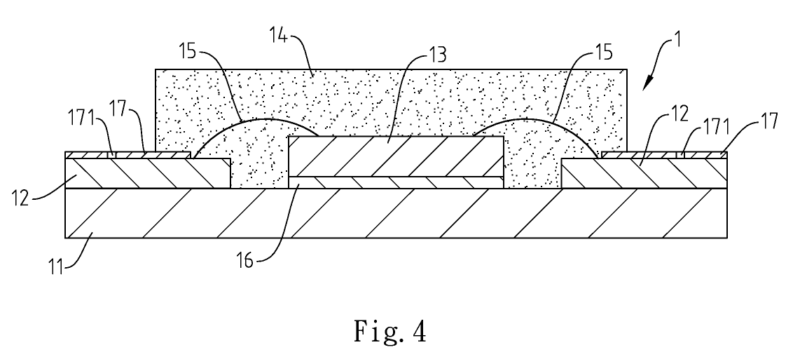

In an alternate form of the present invention, as shown in FIG. 4, the high-power LED package 1 further comprises an insulative covering layer 17 covered on the surface of the circuit layer 12. The insulative covering layer 17 has through holes 171 corresponding to power contacts at the circuit layer 12. During application, the electric wires of the external power source can be inserted through the through holes 17 and electrically connected to the circuit layer 12.

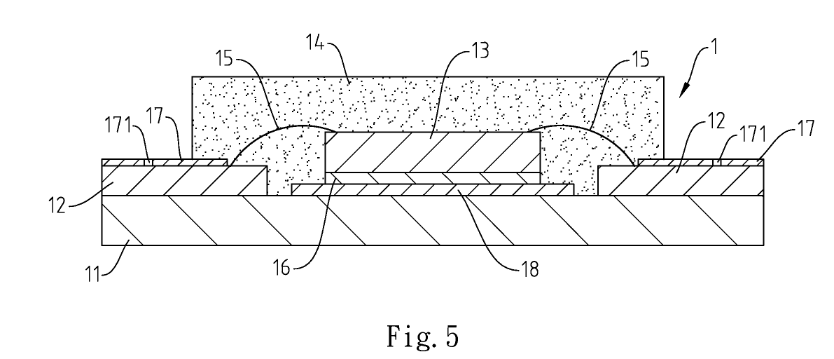

In another alternate form of the present invention, as shown in FIG. 5, a heat transfer layer 18 is sandwiched between the thermal conductive substrate 11 and the bonding layer 16 for quick transfer of waste heat from the LED chip 13 to the thermal conductive substrate 11. This embodiment is suitable for the case in which the thermal conductive substrate 11 is prepared from aluminum, which has excellent heat dissipation property and relatively poor thermal conductivity. Subject to the use of the heat transfer layer 18, waste heat can be rapidly transferred from the LED chip 13 to the thermal conductive substrate 11 for quick dissipation.

By means of the application of the present invention, the performance, life span and reliability of the LED chip 13 are greatly improved and the power consumption is relatively reduced. The technical key point of the invention is based on the principle that: contact point temperature=thermal resistance of package×consumed power+package internal temperature. Waste heat produced during operation of the LED chip 13 is directly transferred to the thermal conductive substrate 11 for quick dissipation. Because the bottom wall of the thermal conductive substrate 11 for quick dissipation is exposed to the outside of the packaging layer 14 and kept in contact with the outside open air, waste heat being transferred from the LED chip 13 to the thermal conductive substrate 11 can be dissipated into the outside open air rapidly. Therefore, the temperature inside of the packaging layer 14 is greatly reduced, and the thermal resistance of the packaging layer 14 works only on a part of the thermal conductive substrate 11. By means of reducing the temperature inside of the packaging layer 14, the contact point temperature is relatively reduced. Thus, the LED chip 13, and therefore the performance, life span and reliability of the LED chip 13 are greatly improved and the power consumption is relatively reduced.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A high-power LED package, comprising:
a thermal conductive substrate, said thermal conductive substrate having opposing top wall and bottom wall;
a circuit layer formed on the top wall of said thermal conductive substrate;
a light emitting diode chip mounted on the top wall of said thermal conductive substrate and electrically connected to said circuit layer; and
a packaging layer covering said light emitting diode chip and a part of said circuit layer outside the bottom wall of said thermal conductive substrate.

2. The high-power LED package as claimed in claim 1, further comprising a plurality of lead wires electrically connected between said light emitting diode chip and said circuit layer.

3. The high-power LED package as claimed in claim 1, further comprising a bonding layer prepared from a solder material and bonded between said light emitting diode chip and the top wall of said thermal conductive substrate.

4. The high-power LED package as claimed in claim 1, further comprising an insulative covering layer covered on the surface of said circuit layer, said insulative covering layer having a plurality of through holes for enabling said circuit layer to be partially exposed to the outside for the connection of an external power source.

5. The high-power LED package as claimed in claim 1, further comprising a heat transfer layer sandwiched between the top wall of said thermal conductive substrate and said light emitting diode chip.
